(19) United States
(12) Patent Application Publication
(10) Pub. No.: US 2013/0203188 A1
(43) Pub. Date: Aug. 8, 2013

(54) HYBRID METROLOGY FOR SEMICONDUCTOR DEVICES

(71) Applicants: Alok Vaid, Ballston Lake, NY (US); Ned R. Saleh, Santa Clara, CA (US); Matthew J. Sendelbach, Fishkill, NY (US); Narender Rana, Highland, NY (US)

(72) Inventors: Alok Vaid, Ballston Lake, NY (US); Ned R. Saleh, Santa Clara, CA (US); Matthew J. Sendelbach, Fishkill, NY (US); Narender Rana, Highland, NY (US)

(73) Assignee: GLOBALFOUNDRIES INC., Grand Cayman (KY)

(21) Appl. No.: 13/365,920

(22) Filed: Feb. 3, 2012

(51) Int. Cl. H01L 21/66; G01B 21/00

(52) U.S. Cl. 438/14; 73/865.8; 257/E21.53

(57) ABSTRACT

Methods and systems are provided for fabricating and measuring physical features of a semiconductor device structure. An exemplary method of fabricating a semiconductor device structure involves forming a first feature of the semiconductor device structure on a substrate of semiconductor material, obtaining a first measurement for the semiconductor device structure from a first metrology tool, obtaining a second measurement of the first feature of the semiconductor device structure from a second metrology tool, and determining a hybrid measurement for the first feature based at least in part on the first measurement and the second measurement.

### TECHNICAL FIELD

Embodiments of the subject matter described herein generally relate to semiconductor device structures and related fabrication methods and metrologies, and more particularly, embodiments of the subject matter relate to determining hybrid measurements of physical features, dimensions, or other attributes of a semiconductor device structure using measurements obtained from different metrology tools.

### BACKGROUND

Semiconductor devices, such as transistors, are the core building block of the vast majority of electronic devices. In practice, it is desirable to accurately and precisely fabricate transistors and other semiconductor devices with physical features having specific physical dimensions, to thereby achieve semiconductor devices having their intended performance characteristics and improve yield. However, the hardware tools used to fabricate the devices may exhibit performance variations. As a result, devices may be fabricated with features that deviate from their specified physical dimensions, which, in turn, could lead to failures at wafer test and/or reduce yield. Thus, it is desirable to measure physical features, critical dimensions and/or other properties of devices during fabrication to correct any deviations from the intended physical dimensions and thereby reduce the likelihood of failures at wafer test and/or improve yield. However, obtaining highly accurate measurements typically takes an undesirably long amount of time or involves destructive metrologies which reduce yield. At the same time, non-destructive measurement tools may be limited in their ability to accurately measure all of the physical features, critical dimensions, and profile information of a device, which, in turn, limits the ability of the foundry (or fab) to maximize yield.

### BRIEF SUMMARY

In one embodiment, an exemplary measurement system is provided. The measurement system includes a first metrology tool and a second metrology tool. The first metrology tool provides a first measurement of a semiconductor device structure and the second metrology tool obtains the first measurement and determines a hybrid measurement of the semiconductor device structure based at least in part on the first measurement.

In another embodiment, a method for fabricating a semiconductor device structure is provided. The method involves obtaining a first measurement for the semiconductor device structure from a first metrology tool, obtaining a second measurement of a first attribute of the semiconductor device structure from a second metrology tool, and determining a hybrid measurement for the first attribute based at least in part on the first measurement and the second measurement.

In yet another embodiment, a method for fabricating a semiconductor device structure involves determining a weighting factor for a first measurement of the semiconductor device structure from a first metrology tool, obtaining a second measurement of the semiconductor device structure from a second metrology tool, determining a hybrid measurement of the semiconductor device structure based at least in part on the first measurement, the second measurement, and the weighting factor, adjusting the weighting factor to reduce a difference between the hybrid measurement and a reference measurement of the semiconductor device structure, and determining a second hybrid measurement of the semiconductor device structure based at least in part on the adjusted weighting factor.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a block diagram of a measurement system in an exemplary embodiment;

FIG. 2 is a block diagram of an exemplary metrology tool suitable for use in the measurement system of FIG. 1 in accordance with one or more embodiments;

FIG. 3 is a flow diagram of an exemplary hybrid measurement process suitable for use with the measurement system of FIG. 1 in an exemplary embodiment; and

FIG. 4 is a flow diagram of an exemplary weighting factor determination process suitable for use in the measurement system of FIG. 1 in connection with the hybrid measurement process of FIG. 3 in accordance with one or more embodiments.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

Embodiments of the subject matter described herein relate to determining hybrid (or composite) measurements of attributes of semiconductor device structures fabricated on a semiconductor substrate using measurements obtained from different metrology tools. Depending on the embodiment, the attribute being measured may be a physical feature, structure or dimension, an absence of a physical feature or structure (e.g., a recess, void or the like), or an intrinsic property (e.g., ion concentration, index of refraction, bulk modulus, electron mobility, or other compositional and/or optical properties). Thus, although the subject matter may be described herein in the context of measuring physical features and/or dimensions of semiconductor device structures, it should be understood that the subject matter is not limited to physical features and/or dimensions and may be utilized to obtain hybrid measurements of intrinsic properties of a semiconductor device structure. As described in greater detail below, a hybrid measurement is calculated using measurements obtained from more than one metrology tool to provide a composite measurement of a particular attribute. For example, in accordance with one or more embodiments, each metrology tool determines measurements of one or more physical features and/or dimensions of a semiconductor device structure based on measurement data measured or otherwise obtained using measurement hardware associated with that metrology tool. The measurements obtained from the different metrology tools are weighted based on their relative accuracy and/or reliability or other characteristics of their respective metrology tool to provide a composite measurement with an accuracy and/or reliability that is greater than the accuracy and/or reliability of the individual measurements obtained by the individual metrology tools.

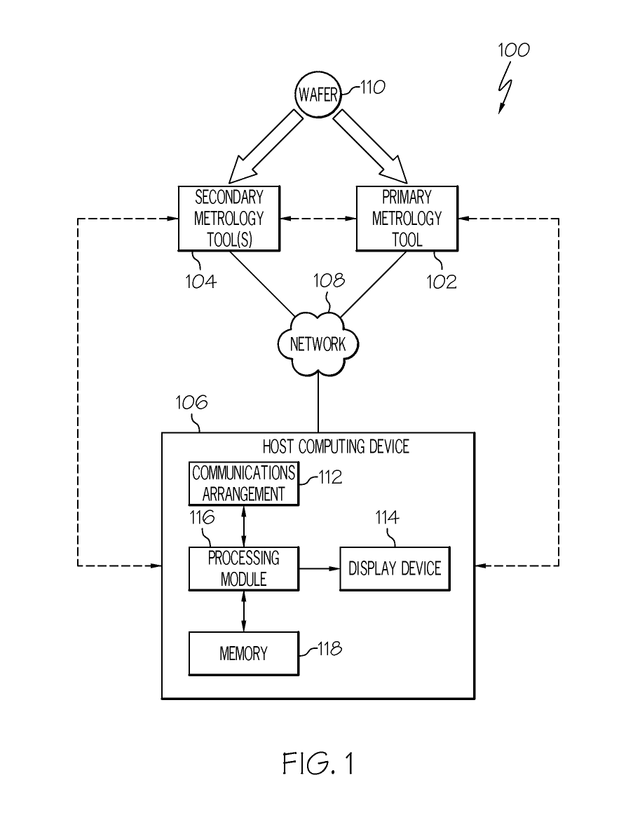

Turning now to FIG. 1, in an exemplary embodiment, a measurement system 100 includes, without limitation, a plurality of metrology tools 102, 104 and a host computing device 106 communicatively coupled over a communications network 108, such as a computer network (e.g., a wide area network, a wireless local area network, or the like), a cellular network, an ad-hoc or peer-to-peer network, or the like. As described in greater detail below, the metrology tools 102, 104 include hardware capable of measuring physical features, dimensions and/or other attributes of one or more semiconductor device structures formed on a substrate (or wafer) 110 of semiconductor material, wherein measurements obtained by the different metrology tools 102, 104 are utilized to augment one another and obtain hybrid (or composite) measurements of the physical features, dimensions and/or attributes. In this regard, a hybrid measurement is calculated or otherwise determined based on different measurements from different metrology tools 102, 104 and other factors in a manner that achieves a composite measurement for a particular physical feature and/or critical dimension of the device structure(s) on the wafer 110 that is more accurate and/or reliable than an individual measurement for that feature and/or dimension from an individual metrology tool 102, 104. It should be understood that FIG. 1 is a simplified representation of the measurement system 100 for purposes of explanation and ease of description, and FIG. 1 is not intended to limit the subject matter in any way. In this regard, practical embodiments of the measurement system 100 may include any number of metrology tools configured to iteratively exchange measurements any number of times to achieve final hybrid measurements having a desired level of accuracy and/or reliability.

In an exemplary embodiment, after fabrication of one or more physical features of the semiconductor device(s) on the wafer 110, the metrology tools 102, 104 are utilized to measure or otherwise quantify the fabricated dimensions of various physical features on the wafer 110 using a measurement technique, such as, for example, scatterometry, scanning electron microscopy, atomic force microscopy, interferometry, reflectometry, ellipsometry, and the like. In this regard, each metrology tool 102, 104 may use a different measurement technique than the other metrology tools 102, 104 in the measurement system 100. In exemplary embodiments, each metrology tool 102, 104 utilizes a non-destructive measurement technique (or technology) so that the wafer 110 is still suitable for its intended operation after being measured. In accordance with one or more embodiments, the host computing device 106 communicates with the metrology tools 102, 104 to signal, command, or otherwise indicate, to a respective metrology tool 102, 104, which features on the wafer 110 are to be measured by that respective metrology tool 102, 104 along with additional information pertaining to how that respective metrology tool 102, 104 should perform the measurement. After a respective metrology tool 102, 104 finishes measuring the physical feature(s) on the wafer 110, the metrology tool 102, 104 may provide the feature measurements to the host computing device 106 and/or another metrology tool 102, 104. In an exemplary embodiment, one metrology tool 102 receives or otherwise obtains the feature measurements from one or more of the other metrology tools 104 for use in determining hybrid measurements for one or more physical feature(s) on the wafer 110, as described in greater detail below. For purposes of explanation, the metrology tool 102 which obtains the feature measurements from the other metrology tools 104 and determines final hybrid measurements is alternatively referred to herein as the primary metrology tool, while the remaining metrology tool(s) 104 in the measurement system 100 are alternatively referred to herein as the secondary metrology tool(s) 104. As described in greater detail below, a secondary metrology tool 104 may also obtain a hybrid measurement determined by the primary metrology tool 102 and potentially other feature measurements from other secondary metrology tool(s) 104 to adjust the feature measurements obtained by the secondary metrology tool 104. Thus, the secondary metrology tool(s) 104 may also determine hybrid (or composite) measurements.

Still referring to FIG. 1, in an exemplary embodiment, the host computing device 106 includes, without limitation, a communications arrangement 112, a display device 114, a processing module 116, and memory 118. The communications arrangement 112 generally represents the hardware, software, firmware and/or combination thereof which are coupled to the processing module 116 and cooperatively configured to support communications between the host computing device 106 and the metrology tools 102, 104 via the network 108. The display device 114 is realized as an electronic display (e.g., a liquid crystal display (LCD), a light emitting diode (LED) display, or the like) configured to graphically display information and/or content under control of the processing module 116. The processing module 116 generally represents the hardware, firmware, processing logic, and/or other components of the host computing device 106 configured to support operation of the host computing device 106 and execute various functions and/or processing tasks as described in greater detail below. Depending on the embodiment, the processing module 116 may be implemented or realized with a general purpose processor, a microprocessor, a controller, a microcontroller, a state machine, a content addressable memory, an application specific integrated circuit, a field programmable gate array, any suitable programmable logic device, discrete gate or transistor logic, discrete hardware components, or any combination thereof, designed to perform the functions described herein. Furthermore, the steps of a method or algorithm described in connection with the embodiments disclosed herein may be embodied directly in hardware, in firmware, in a software module executed by the processing module 116, or in any practical combination thereof. The memory 118 generally represents any non-transitory short or long term storage media capable of storing programming instructions for execution by the processing module 116, including any sort of random access memory (RAM), read only memory (ROM), flash memory, registers, hard disks, removable disks, magnetic or optical mass storage, and/or the like. The programming instructions, when read and executed by the processing module 116, cause the processing module 116 to perform certain tasks, operations, functions, and processes described in more detail below.

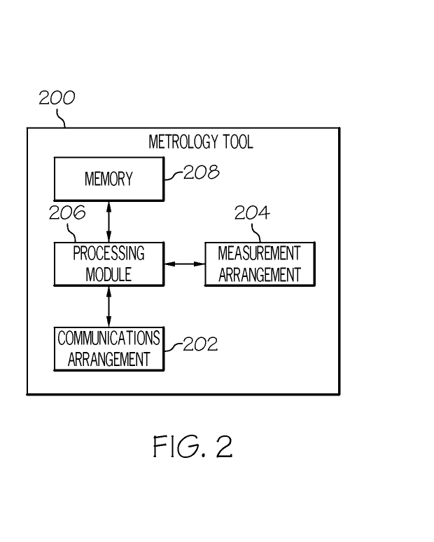

FIG. 2 depicts an exemplary embodiment of a metrology tool 200 suitable for use as a metrology tool 102, 104 in the measurement system 100 of FIG. 1. The illustrated metrology tool 200 includes, without limitation, a communications arrangement 202, measurement arrangement 204, a processing module 206, and memory 208. It should be understood that FIG. 2 is a simplified representation of the metrology tool 200 for purposes of explanation and ease of description, and FIG. 2 is not intended to limit the subject matter in any way.

In the illustrated embodiment, the communications arrangement 202 generally represents the hardware, software, firmware and/or combination thereof which are coupled to the processing module 206 and cooperatively configured to support communications to/from the metrology tool 200 via a network (e.g., network 108) in a conventional manner. The measurement arrangement 204 generally represents the combination of radiation sources, illumination devices, electron guns, sensors, optics, and/or other hardware components of the metrology tool 200 which are utilized to measure physical features, dimensions and/or other attributes of semiconductor devices on a wafer. In accordance with one or more embodiments, the measurement arrangement 204 is capable of transmitting, emitting, or otherwise directing a reference signal towards a wafer and sensing, receiving, or otherwise measuring a response signal from the wafer. In this regard, the physical features, dimensions and/or other attributes of the wafer modulate or otherwise influence characteristics of the reference signal resulting in the response signal that is sensed or otherwise received by the measurement arrangement 204. Thus, the response signal corresponds to raw feature measurement data that is indicative of the dimensions of the various physical features, dimensions and/or other attributes on the wafer 110, which can be determined based on characteristics of the response signal (e.g., the spectral characteristics, waveforms, or the like) or the relationship between the response signal and the reference signal.

The processing module 206 generally represents the hardware, firmware, processing logic, and/or other components of the metrology tool 200 configured to control or otherwise operate the measurement arrangement 204 to measure physical features and/or dimensions on a wafer, communicate feature measurements to/from the metrology tool 200, store feature measurements in the memory 208, and execute various functions and/or processing tasks as described in greater detail below. Depending on the embodiment, the processing module 206 may be implemented or realized with a general purpose processor, a microprocessor, a controller, a microcontroller, a state machine, a content addressable memory, an application specific integrated circuit, a field programmable gate array, any suitable programmable logic device, discrete gate or transistor logic, discrete hardware components, or any combination thereof, designed to perform the functions described herein. Furthermore, the steps of a method or algorithm described in connection with the embodiments disclosed herein may be embodied directly in hardware, in firmware, in a software module executed by the processing module 206, or in any practical combination thereof. The memory 208 represents any non-transitory short or long term storage media capable of storing programming instructions for execution by the processing module 206, which, when read and executed by the processing module 206, cause the processing module 206 to perform certain tasks, operations, functions, and processes described in more detail herein. In accordance with one or more embodiments, the memory 208 also stores feature measurements obtained using the measurement arrangement 204 and/or feature measurements obtained from other metrology tools, as described in greater detail below.

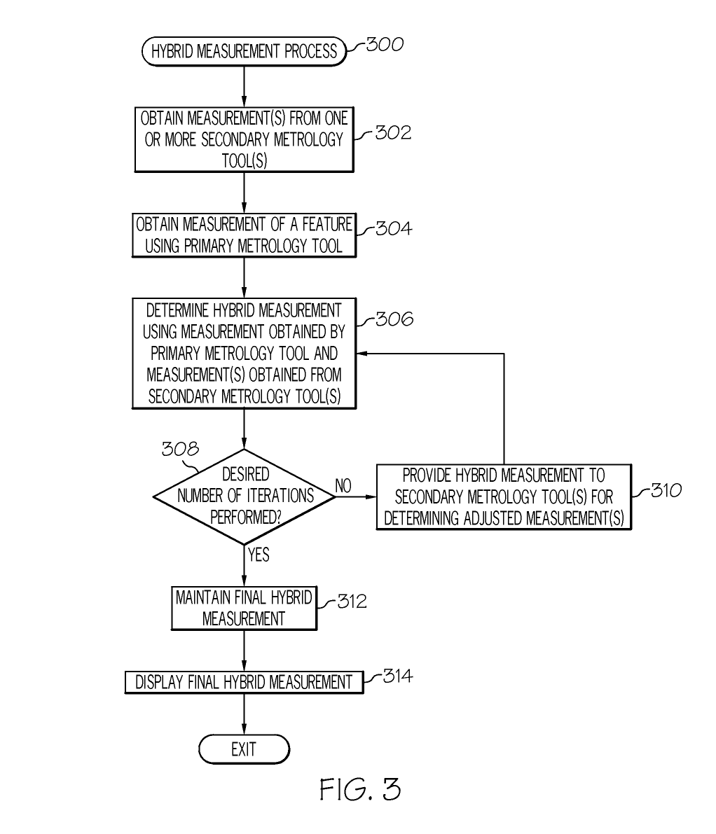

FIG. 3 depicts an exemplary hybrid measurement process 300 suitable for implementation by a measurement system 100 to obtain hybrid measurements of physical features and/or dimensions of semiconductor devices. The various tasks performed in connection with the hybrid measurement process 300 may be performed by software, hardware, firmware, or any combination thereof. For illustrative purposes, the following description refers to elements mentioned above in connection with FIGS. 1-2. In practice, portions of the hybrid measurement process 300 may be performed by different elements of the measurement system 100, such as, for example, the primary metrology tool 102, the secondary metrology tool(s) 104, and/or the host computing device 106. It should be appreciated that the hybrid measurement process 300 may include any number of additional or alternative tasks, the tasks need not be performed in the illustrated order and/or the tasks may be performed concurrently, and/or the hybrid measurement process 300 may be incorporated into a more comprehensive procedure or process having additional functionality not described in detail herein. Moreover, one or more of the tasks shown and described in the context of FIG. 3 could be omitted from a practical embodiment of the hybrid measurement process 300 as long as the intended overall functionality remains intact.

Referring to FIG. 3, and with continued reference to FIGS. 1-2, in an exemplary embodiment, the hybrid measurement process 300 begins by obtaining measurements for one or more physical features, dimensions and/or other attributes on a wafer from one or more secondary metrology tool(s) (task 302). For example, after the physical features and/or dimensions to be measured have been fabricated, the wafer 110 is placed in a chamber proximate to or otherwise associated with a secondary metrology tool 104 such that the wafer 110 is aligned with the measurement arrangement 204 of the secondary metrology tool 104. In accordance with one or more embodiments, the secondary metrology tool 104 notifies the host computing device 106 of the presence of the wafer 110, wherein the host computing device 106 provides commands and/or instructions to the secondary metrology tool 104 to initiate measurement of the semiconductor device structures on the wafer 110. In response to receiving commands and/or instructions from the host computing device 106, the processing module 206 of the secondary metrology tool 104 signals or otherwise operates the measurement arrangement 204 to measure the physical features and/or dimensions on the wafer 110 in the manner indicated by the host computing device 106. As described above, in accordance with one or more embodiments, to measure physical features and/or dimensions on the wafer 110, the measurement arrangement 204 transmits or otherwise directs a reference signal towards the wafer 110, wherein the physical features of the wafer 110 modulate or otherwise influence the reference signal resulting in a response signal that is sensed or otherwise received by the measurement arrangement 204. The processing module 206 receives or otherwise obtains the raw feature measurement data from the measurement arrangement 204, calculates or otherwise determines measurements for the corresponding physical features and/or critical dimensions on the wafer 110 based on characteristics of the response signal (e.g., the response signal spectra, waveforms, or the like), and stores or otherwise maintains the feature measurements in memory 208. The secondary metrology tool 104 communicates or otherwise provides the obtained feature measurements to the host computing device 106 and/or the primary metrology tool 102 for use in determining hybrid measurements for physical features and/or critical dimensions on the wafer 110, as described in greater detail below.

In an exemplary embodiment, the hybrid measurement process 300 also obtains measurements for one or more physical features, dimensions and/or other attributes on a wafer from the primary metrology tool (task 304). In a similar manner as described above, the wafer 110 is placed in a chamber proximate to or otherwise associated with a primary metrology tool 102 such that the wafer 110 is aligned with the measurement arrangement 204 of the primary metrology tool 102, and the host computing device 106 provides commands and/or instructions to the primary metrology tool 102 regarding which physical features and/or dimensions on the wafer 110 should be measured. In response to receiving commands and/or instructions from the host computing device 106, the processing module 206 of the primary metrology tool 102 signals or otherwise operates the measurement arrangement 204 to measure the physical features and/or dimensions on the wafer 110 in the manner indicated by the host computing device 106. The processing module 206 of the primary metrology tool 102 receives or otherwise obtains the raw feature measurement data from the measurement arrangement 204, calculates or otherwise determines measurements for the physical features and/or critical dimensions on the wafer 110 utilizing the raw feature measurement data, and stores or otherwise maintains the feature measurements in its memory 208.

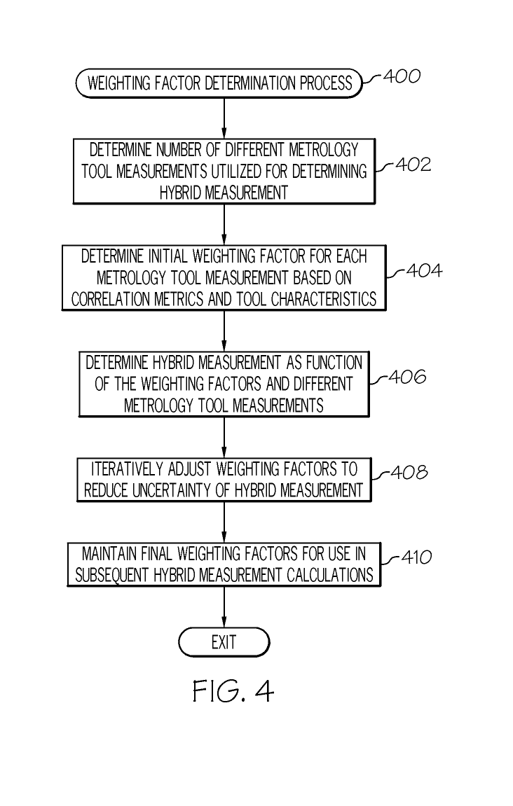

In an exemplary embodiment, the hybrid measurement process 300 continues by calculating or otherwise determining hybrid measurements for one or more physical features, dimensions and/or other attributes of the wafer based on the feature measurements obtained using the secondary metrology tool(s) and the feature measurements obtained using the primary metrology tool (task 306). In an exemplary embodiment, the hybrid feature measurements for a particular feature and/or dimension are calculated as a function of the measurement for that feature and/or dimension obtained using the primary metrology tool 102 and one or more feature measurements from one or more secondary metrology tool(s) 104. The secondary metrology tool feature measurement(s) used in determining a hybrid measurement for a feature may be for that feature or a different feature on the wafer 110. In an exemplary embodiment, the primary metrology tool 102 and/or the host computing device 106 determines the hybrid measurement for a particular feature and/or dimension by weighting the primary metrology tool feature measurement and the secondary metrology tool feature measurement(s) in accordance with their relative accuracy and/or reliability. For example, as described in greater detail below in the context of FIG. 4, for each respective secondary metrology tool 104, the metrology tool 102 and/or the host computing device 106 may determine a weighting factor representative of the relative quality of feature measurements from that secondary metrology tool 104 with respect to the metrology tool 102 and/or the other secondary metrology tools 104 in the measurement system 100. In this regard, the quality weighting factor for a particular metrology tool 102, 104 may be based on or influenced by the total measurement uncertainty (TMU) and/or reference measurement system uncertainty (RMSU) of the respective metrology tool 102, 104 along with other characteristics of the respective metrology tool 102, 104 that may influence measurement quality.

In accordance with one embodiment, the metrology tool 102 and/or the host computing device 106 calculates the hybrid measurement for a particular feature on the wafer 110 as a weighted sum of the feature measurements from the secondary tool(s) 104 and the metrology tool 102 using the quality weighting factors. For example, for a particular critical dimension measured by the primary metrology tool 102 and a secondary metrology tool 104, the metrology tool 102 may calculate a hybrid measurement of a critical dimension (CD) using the equation CD_{H}=γ_{S1}CD_{S}+γ_{P1}CD_{P}, where CD_{S} is the measurement for the critical dimension that was determined or otherwise measured by the secondary tool 104, CD_{P} is the measurement for the critical dimension that was determined or otherwise measured by the primary metrology tool 102, γ_{S1} is the quality weighting factor associated with the secondary metrology tool 104 determined by the primary metrology tool 102, and γ_{P1} is the quality weighting factor associated with the primary metrology tool 102. In one embodiment, the sum of the quality weighting factors is equal to one, where γ_{P1}=1−γ_{S1}, such that the quality weighting factor associated with the primary metrology tool corresponds to and compensates for the relative difference between the secondary tool feature measurement (e.g., CD_{S}) and the weighted secondary tool feature measurement (e.g., γ_{S1}CD_{S}). As described above, in some embodiments, the secondary tool feature measurement may be for a different physical feature and/or dimension than the primary tool feature measurement. For example, the secondary metrology tool 104 may be realized as an atomic force microscopy (AFM) tool that measures a sidewall angle of a gate structure fabricated on the wafer 110 and the primary metrology tool 102 may be realized as a optical critical dimension (OCD) tool that measures a gate dielectric undercut and determines a hybrid measurement for the gate dielectric undercut based on its own measurement of the gate dielectric undercut and the measurement of the gate sidewall angle obtained from the AFM metrology tool.

Still referring to FIG. 3, in an exemplary embodiment, the hybrid measurement process 300 continues by identifying or otherwise determining whether a desired number of iterations have been performed, and when the desired number of iterations have not been performed, providing the hybrid measurement(s) to one or more of the secondary metrology tool(s) for adjusting the feature measurements obtained by the respective secondary metrology tool (tasks 308, 310). For example, in accordance with one or more embodiments, after the primary metrology tool 102 calculates hybrid measurements using the feature measurements measured by the metrology tool 102 and feature measurements measured by the secondary metrology tool(s) 104, the metrology tool 102 provides the hybrid measurements for the physical features and/or dimensions on the wafer 110 to the host computing device 106. When the host computing device 106 determines that a desired number of iterations have not been performed, the host computing device 106 either transmits the hybrid measurements obtained from the metrology tool 102 to one or more of the secondary metrology tools 104 or the host computing device 106 signals the metrology tool 102 to transmit the hybrid measurement to the one or more secondary metrology tools 104. After the secondary metrology tool 104 obtains the hybrid measurement for a particular physical feature and/or dimension from the primary metrology tool 102, the secondary metrology tool 104 calculates or otherwise determines an adjusted measurement for a particular physical feature and/or dimension (which may or may not be the same feature corresponding to the hybrid measurement) using the hybrid measurement determined by the primary metrology tool 102 and the previous feature measurement measured by the secondary metrology tool 104 (e.g., the feature measurement previously calculated using the raw feature measurement data obtained using its measurement arrangement 204). In this regard, in a similar manner as described above, the secondary metrology tool 104 may determine quality weighting factors and calculate the adjusted feature measurement as a weighted sum of the hybrid feature measurement determined by the primary metrology tool 102 and the feature measurement obtained using its own measurement hardware. Thus, the hybrid measurement determined by the primary metrology tool 102 is utilized to augment or otherwise modify the feature measurements determined by the secondary tool 104. For example, the secondary metrology tool 104 may calculate an adjusted measurement of the critical dimension (CD) using the equation CD_{S}_{_{—}}_{ADJ}=γ_{S2}CD_{S}+γ_{P2}CD_{H}, where CD_{S} is the previous measurement for the critical dimension determined by the secondary metrology tool 104, CD_{H} is the hybrid measurement for the critical dimension that was determined by the primary metrology tool 102, γ_{S2} is the quality weighting factor associated with the secondary metrology tool 104 determined by the secondary metrology tool 104, and γ_{P2} is the quality weighting factor associated with the primary metrology tool 102 determined by the secondary metrology tool 104. In this regard, the adjusted secondary metrology tool feature measurement is also a hybrid (or composite) feature measurement.

After a secondary metrology tool determines an adjusted feature measurement, the hybrid measurement process 300 repeats the step of determining a hybrid measurement for that physical feature and/or dimension based on the adjusted feature measurements determined by the secondary metrology tool(s) 104 (task 306). In this regard, the primary metrology tool 102 obtains an adjusted feature measurement from a secondary metrology tool 104 and calculates an adjusted hybrid feature measurement as a function of the adjusted feature measurement and the previous feature measurement determined by the metrology tool 102. In one or more embodiments, the metrology tool 102 calculates the adjusted hybrid measurement as a weighted sum of the previous feature measurement determined by the primary metrology tool 102 and the adjusted feature measurement determined by the secondary metrology tool 104. For example, the metrology tool 102 may calculate an adjusted hybrid measurement of a critical dimension (CD) using the equation CD_{H}_{_{—}}_{ADJ}=γ_{S1}CD_{S}_{_{—}}_{ADJ}+γ_{P1}CD_{P}, where CD_{S}_{_{—}}_{ADJ} is the adjusted measurement for the critical dimension determined by the secondary metrology tool 104, CD_{P} is the measurement for the critical dimension that was obtained using the measurement hardware of the primary metrology tool 102. In this manner, the adjusted secondary metrology tool feature measurement augments or otherwise modifies the hybrid measurement determined by the primary metrology tool 102.

In an exemplary embodiment, the hybrid measurement process 300 repeats the steps of iteratively adjusting the secondary metrology tool measurements and determining updated hybrid feature measurements until a desired number of iterations have been performed (tasks 306, 308, 310). In this regard, the desired number of iterations to be performed is chosen to achieve final hybrid feature measurements having a desired level of accuracy and/or reliability. For example, in one or more embodiments, the metrology tool 102 provides the hybrid feature measurements determined at the end of each iteration to the host computing device 106. In accordance with one exemplary embodiment, the host computing device 106 determines that the desired number iterations have been performed when the difference between successive hybrid feature measurements provided by the primary metrology tool 102 is less than a threshold amount. For example, when a hybrid feature measurement determined by the metrology tool 102 differs from the previous hybrid feature measurement provided by the metrology tool 102 by less than a threshold amount (e.g., a percentage of the previous hybrid feature measurement or a fixed amount), the host computing device 106 commands, signals, or otherwise indicates to the metrology tools 102, 104 that the desired number of iterations have been performed. In other embodiments, the host computing device 106 counts or otherwise monitors the number of iterations performed by the metrology tool 102 and commands, signals, or otherwise indicates to the metrology tools 102, 104 that the desired number of iterations have been performed when the counted number of iterations exceeds a threshold number chosen to result in hybrid measurements with a desired accuracy and/or reliability. After the desired number of iterations have been performed, the hybrid measurement process 300 stores or otherwise maintains the final hybrid measurements for the physical features and/or dimensions of the semiconductor devices on the wafer 110 in memory and displays or otherwise presents the final hybrid measurements to the user (tasks 312, 314). In this regard, the processing module 116 stores the final hybrid measurements obtained from the metrology tool 102 in memory 118, and when a user subsequently accesses the host computing device 106 to view measurements for the physical features and/or dimensions on the wafer 110, the processing module 116 presents or otherwise displays the final hybrid measurements (or a graphical representation thereof) on the display device 114.

FIG. 4 depicts an exemplary weighting factor determination process 400 suitable for implementation by a measurement system 100 in connection with the hybrid measurement process 300 of FIG. 3 to determine quality weighting factors. The various tasks performed in connection with the weighting factor determination process 400 may be performed by software, hardware, firmware, or any combination thereof. For illustrative purposes, the following description refers to elements mentioned above in connection with FIGS. 1-2. In practice, portions of the weighting factor determination process 400 may be performed by different elements of the measurement system 100, such as, for example, the primary metrology tool 102, the secondary metrology tool(s) 104, and/or the host computing device 106. It should be appreciated that the weighting factor determination process 400 may include any number of additional or alternative tasks, the tasks need not be performed in the illustrated order and/or the tasks may be performed concurrently, and/or the weighting factor determination process 400 may be incorporated into a more comprehensive procedure or process having additional functionality not described in detail herein. Moreover, one or more of the tasks shown and described in the context of FIG. 4 could be omitted from a practical embodiment of the weighting factor determination process 400 as long as the intended overall functionality remains intact.

In an exemplary embodiment, the weighting factor determination process 400 begins by determining or otherwise identifying the number of different feature measurements from different metrology tools to be utilized by a particular tool in determining a hybrid measurement (task 402). For example, the primary metrology tool 102 may identify the total number of secondary metrology tools 104 in the system as the number of different feature measurements to be utilized by the metrology tool 102 when determining hybrid measurements. After identifying the number of different feature measurements to be utilized, the weighting factor determination process 400 continues by determining initial quality weighting factors for each respective feature measurement based on correlation metrics for the respective feature measurement and/or characteristics of the metrology tool associated with the respective feature measurement (task 404). In accordance with one embodiment, the metrology tool 102 determines a numerical range for the quality weighting factors, and then determines, for each respective feature measurement, an initial quality weighting factor value based on one or more correlation metrics (e.g., TMU, RMSU, R² values or other correlation coefficients, and the like) associated with that feature measurement and/or one or more characteristics of the secondary metrology tool 104 (e.g., FMP or other tool matching metrics, the precision of the tool, the throughput of the tool, the configuration and/or type of tool, the age of the tool, performance characteristics of the measurement arrangement, and the like) providing that feature measurement that are likely to impact the reliability of that feature measurement. In other words, each quality weighting factor is determined as a function of one or more correlation metrics and/or one or more characteristics of the respective metrology tool providing that feature measurement to reduce or otherwise eliminate measurement noise and thereby improve the metrology performance of the hybrid measurement using that feature measurement. The initial quality weighting factor associated with a feature measurement provided by a first secondary metrology tool 104 may be greater than the initial quality weighting factor associated with a feature measurement provided by a second secondary metrology tool 104 when the correlation metric(s) and/or tool characteristic(s) of the first secondary metrology tool 104 are indicative of the measurements from the first secondary metrology tool 104 being more accurate than measurements from the second secondary metrology tool 104, and vice versa.

Still referring to FIG. 4, in an exemplary embodiment, after determining initial quality weighting factors for the different measurements, the weighting factor determination process 400 continues by determining an initial hybrid measurement as a function of the initial quality weighting factors and different measurements from the different metrology tools (task 406). For example, the metrology tool 102 determines an initial hybrid measurement for a physical feature and/or dimension as a function of the measurement for that feature and/or dimension obtained using the metrology tool 102, the quality weighting factor associated with the metrology tool 102, one or more additional measurements obtained from one or more of the secondary metrology tools 104, and the initial quality weighting factors associated with those one or more additional measurements and/or secondary metrology tools 104 in a similar manner as described above. After determining an initial hybrid measurement, the weighting factor determination process 400 continues by iteratively adjusting the quality weighting factors to reduce the uncertainty of the hybrid measurement by reducing the difference between the hybrid measurement and a reference measurement (task 408). In this regard, the equation and/or function used to calculate a hybrid measurement is optimized by adjusting the different weighting factors used to calculate the hybrid measurement. For example, in accordance with one embodiment, a reference measurement for the physical feature and/or dimension may be obtained using a highly accurate metrology, such as transmission electron microscopy (TEM). Using the reference measurement, the metrology tool 102 may iteratively adjust one or more of the quality weighting factors associated with one or more of the measurements obtained from the secondary metrology tools 104 to reduce or eliminate the difference between the hybrid measurement calculated by the metrology tool 102 and the reference measurement. In this regard, in some embodiments, the metrology tool 102 may modify any equations and/or functions used to determine the initial quality weighting factors so that those equations and/or functions provide different quality weighting factor values that reduce the difference (or error) between the hybrid measurement and the reference measurement. In other embodiments, the metrology tool 102 may determine the hybrid measurement multiple times using different feature measurement values obtained using the metrology tools 102, 104 (e.g., by measuring the same wafer and/or semiconductor devices multiple times), wherein the metrology tool 102 iteratively adjusts the quality weighting factors to reduce or eliminate the difference between the different hybrid measurements calculated by the metrology tool 102. In other words, the metrology tool 102 quality weighting factors are iteratively adjusted so that the different hybrid measurements converge to reduce the difference between the different hybrid measurements until the difference between the different hybrid measurements is below a threshold amount. In this regard, a previous and/or subsequent hybrid measurement functions as a reference measurement when adjusting the quality weighting factors.

After iteratively adjusting the quality weighting factors to optimize the hybrid measurement calculation, the weighting factor determination process 400 continues by maintaining the final quality weighting factors for use in subsequent hybrid measurement determinations (task 410). In an exemplary embodiment, the metrology tool 102 stores the final quality weighting factors (or the final quality weighting factor equations and/or functions) resulting from the iterative adjustments in its memory 208 for use in calculating subsequent hybrid measurements, as described above in the context of the hybrid measurement process 300. In other embodiments, the metrology tool 102 may provide the final quality weighting factors to the host computing device 106, which maintains the quality weighting factors in memory 118. In an exemplary embodiment, the weighting factor determination process 400 is performed for each different hybrid measurement determined by a metrology tool 102, 104 and/or the host computing device 106, including the adjusted measurements determined by the secondary metrology tools 104 and/or the host computing device 106, as described above.

To briefly summarize, one advantage of the hybrid measurement process 300 and the weighting factor determination process 400 is that accurate and/or reliable hybrid measurements for physical features and/or dimensions on a wafer are determined using measurements from different metrology tools, which might otherwise provide less accurate and/or less reliable measurements. To put it another way, composite measurements determined as a function of measurements from different non-destructive metrology tools may achieve a level of accuracy and/or reliability on par with highly accurate metrology tools which require longer amounts of measurement time and/or rely on destructive metrology techniques. Thus, highly accurate measurements can be obtained in a reduced amount of time and in a non-destructive manner by combining independent measurements from different metrology tools, as described above, thereby allowing a foundry or other fabrication entity to achieve a higher yield. For example, a foundry may fabricate a particular physical feature and/or dimension of interest for a semiconductor device or integrated circuit on a wafer of semiconductor material using conventional semiconductor fabrication techniques and utilize multiple metrology tools to measure that physical feature and/or dimensions and determine a hybrid measurement of that physical feature and/or dimension which is accurate and/or reliable without utilizing a destructive metrology technique (e.g., TEM or the like), thereby allowing the semiconductor device structure to function in the desired manner after being measured.

For the sake of brevity, conventional techniques related to correlation and/or uncertainty analysis, semiconductor metrology tools and/or methods, semiconductor fabrication, and other functional aspects of the systems (and the individual operating components of the systems) are not described in detail herein. While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A measurement system comprising:
a first metrology tool to provide a first measurement of a semiconductor device structure; and
a second metrology tool configured to:
obtain the first measurement; and
determine a hybrid measurement of the semiconductor device structure based at least in part on the first measurement.

2. The measurement system of claim 1, wherein:
the first metrology tool is configured to measure a first feature of the semiconductor device structure to obtain the first measurement of the first feature; and
the second metrology tool is configured to:
measure the first feature of the semiconductor device structure to obtain a second measurement of the first feature; and
determine the hybrid measurement for the first feature based at least in part on the first measurement and the second measurement.

3. The measurement system of claim 2, wherein the second metrology tool is configured to determine the hybrid measurement by determining a weighted sum of the first measurement and the second measurement.

4. The measurement system of claim 3, wherein the second metrology tool is configured to determine the weighted sum by multiplying the first measurement by a first weighting factor to obtain a weighted first measurement.

5. The measurement system of claim 4, wherein the first weighting factor is based at least in part on a correlation metric associated with the first measurement or a characteristic of the first metrology tool.

6. The measurement system of claim 4, wherein the second metrology tool is configured to determine the weighted sum by:
multiplying the second measurement by a second weighting factor to obtain a weighted second measurement; and
adding the weighted first measurement and the weighted second measurement to obtain the hybrid measurement.

7. The measurement system of claim 1, wherein:
the first metrology tool is configured to measure a first feature of the semiconductor device structure to obtain the first measurement for the first feature; and
the second metrology tool is configured to determine the hybrid measurement of a second feature of the semiconductor device structure based at least in part on the first measurement of the first feature.

8. The measurement system of claim 1, wherein the second metrology tool is configured to:
obtain a second measurement of the semiconductor device structure; and
determine the hybrid measurement based at least in part on the first measurement and the second measurement.

9. The measurement system of claim 8, wherein:
the first metrology tool is configured to:
obtain the hybrid measurement; and
determine an adjusted measurement of the semiconductor device structure based at least in part on the hybrid measurement; and
the second metrology tool is configured to:
obtain the adjusted measurement; and
determine an adjusted hybrid measurement of the semiconductor device structure based at least in part on the adjusted measurement and the second measurement.

10. The measurement system of claim 1, wherein the first metrology tool and the second metrology tool are each coupled to a network, the second metrology tool obtaining the first measurement via the network.

11. The measurement system of claim 1, wherein:
the first metrology tool comprises:
a first measurement arrangement to measure the semiconductor device structure to obtain first measurement data; and
a first processing module coupled to the first measurement arrangement to determine the first measurement based on the first measurement data; and
the second metrology tool comprises:
a second measurement arrangement to measure a first feature of the semiconductor device structure to obtain second measurement data; and
a second processing module coupled to the second measurement arrangement to:
determine a second measurement based on the second measurement data; and
determine the hybrid measurement of the first feature based at least in part on the second measurement and the first measurement.

12. A method of fabricating a semiconductor device structure, the method comprising:
obtaining a first measurement for the semiconductor device structure from a first metrology tool;
obtaining a second measurement of a first attribute of the semiconductor device structure from a second metrology tool; and
determining a hybrid measurement for the first attribute based at least in part on the first measurement and the second measurement.

13. The method of claim 12, wherein:
obtaining the first measurement comprises obtaining, by a primary metrology tool, the first measurement for the semiconductor device structure from a secondary metrology tool; and
obtaining the second measurement comprises obtaining the second measurement of a first feature of the semiconductor device structure using the primary metrology tool.

14. The method of claim 13, wherein determining the hybrid measurement comprises determining, by the primary metrology tool, the hybrid measurement for the first feature.

15. The method of claim 12, further comprising:
providing the hybrid measurement to the first metrology tool, wherein the first metrology tool provides an adjusted measurement based at least in part on the hybrid measurement;
obtaining the adjusted measurement from the first metrology tool; and
determining an adjusted hybrid measurement for the first attribute based at least in part on the adjusted measurement and the second measurement.

16. The method of claim 12, wherein determining the hybrid measurement comprises:
multiplying the first measurement by a weighting factor, resulting in a weighted first measurement; and
determining the hybrid measurement based at least in part on the weighted first measurement and the second measurement.

17. The method of claim 16, further comprising determining the weighting factor based on a correlation metric associated with the first measurement or a characteristic of the first metrology tool.

18. The method of claim 16, further comprising forming a first feature of the semiconductor device structure on a substrate of semiconductor material prior to obtaining the second measurement, wherein obtaining the second measurement comprises obtaining the second measurement of the first feature of the semiconductor device structure using the second metrology tool.

19. A method of fabricating a semiconductor device structure, the method comprising:
determining a weighting factor for a first measurement of the semiconductor device structure from a first metrology tool;
obtaining a second measurement of the semiconductor device structure from a second metrology tool;
determining a hybrid measurement of the semiconductor device structure based at least in part on the first measurement, the second measurement, and the weighting factor;
adjusting the weighting factor to reduce a difference between the hybrid measurement and a reference measurement of the semiconductor device structure, resulting in an adjusted weighting factor; and
determining a second hybrid measurement of the semiconductor device structure based at least in part on the adjusted weighting factor.

20. The method of claim 19, wherein determining the second hybrid measurement comprises:
obtaining a third measurement of the semiconductor device structure from the first metrology tool;
obtaining a fourth measurement of the semiconductor device structure from the second metrology tool;
determining the second hybrid measurement of the semiconductor device structure based at least in part on the third measurement, the fourth measurement, and the adjusted weighting factor.
